(19) United States
(12) Patent Application Publication
(10) Pub. No.: US 2012/0211063 A1
(43) Pub. Date: Aug. 23, 2012

(54) Back Contact Solar Cell with Organic Semiconductor Heterojunctions

(76) Inventors: Jong-Jan Lee, Camas, WA (US); Paul J. Schuele, Washougal, WA (US)

(21) Appl. No.: 13/215,279

(22) Filed: Aug. 23, 2011

Related U.S. Application Data
(63) Continuation-in-part of application No. 12/405,962, filed on Mar. 17, 2009.

(51) Int. Cl. H01L 31/0352; H01L 51/46

(52) U.S. Cl. 136/255; 438/72; 136/263; 257/E51.026

(57) ABSTRACT

A back contact solar cell with organic semiconductor heterojunctions is provided. The substrate is made from silicon lightly doped with a first dopant type having a first majority carrier. A second semiconductor layer is formed overlying the texturized substrate topside, made from hydrogenated amorphous silicon (a-Si:H) and doped with the first dopant. An antireflective coating is formed overlying the second semiconductor layer. A third semiconductor layer is formed overlying the first semiconductor substrate backside, made from intrinsic a-Si:H. First and second majority carrier type organic semiconductor layers are formed overlying the third semiconductor layer in patterns. A dielectric organic semiconductor layer is formed overlying the first majority carrier type organic semiconductor layer and the second majority carrier type organic semiconductor layer, filling the spaces in the pattern. A first metal grid is connected to first organic semiconductor contact regions and a second metal grid is connected to the second organic semiconductor contact regions.

### RELATED APPLICATIONS

This application is a Continuation-in-Part of a patent application entitled, SINGLE HETEROJUNCTION BACK CONTACT SOLAR CELL, invented by Jong-Jan Lee et al., Ser. No. 12/405,962, filed Mar. 17, 2009, Attorney Docket No. SLA2945, which is incorporated herein by reference.

### BACKGROUND OF THE INVENTION

1. Field of the Invention

This invention generally relates to solar cell fabrication and, more particularly, to an organic semiconductor heterojunction back contact solar cell and associated fabrication process.

2. Description of the Related Art

FIG. 1 is a partial cross-sectional view of a conventional silicon solar cell (prior art). The starting silicon wafer is usually lightly boron (p) doped. The emitter layer is formed by phosphorous (n) diffusion on the wafer front surface, and the back surface field is formed by either boron diffusion or by silicon-aluminum (Si—Al) eutectic formation. The front surface has antireflection coating (ARC) and surface texturing to reduce the light reflection and improve the cell efficiency. The front grid contacts the emitter layer (n-doped region) and the back metal contacts the back surface field (p-doped) region. The limitations of this cell are

(a) shading loss due to the metal grid;

(b) series resistance loss at the front metal grid and emitter resistance;

(c) front surface recombination loss at the emitter junction; and,

(d) rear surface recombination loss due to the low Al back surface passivation quality.

FIG. 2 is a partial cross-sectional view depicting a back contact solar cell (prior art). To reduce the front surface reflection loss and series resistance loss caused by the metal grid, the back contact solar cell was developed. For this cell, there is no shadowing effect, since there is no grid on the top surface. Series resistance is very low because the metal grid on the backside can be wide. Light trapping is improved because the front surface is decoupled from the electrical performance and only impacts the optical performance. Further, the cell has a simple electrical connection. A record cell efficiency of 23.4% has been reported. However, a high quality (single-crystal) silicon wafer is needed, so the photo-generated carriers can migrate to the wafer backside for collection.

Although a high efficiency back contact cell has been reported, the open circuit voltage (V_{OC}) for this cell is usually less than 0.7V. This voltage clearly indicates that the surface recombination at the back contact junctions. To increase the V_{OC}, it is necessary to reduce the surface recombination.

FIG. 3 is a perspective drawing depicting a heterojunction solar cell (prior art). It is generally agreed that heterojunctions create a minority carrier reflection mirror that can reduce the surface recombination and increase the V_{OC}. For Si solar cell, the hydrogenated amorphous silicon to crystalline silicon (a-Si:H/c-Si) heterojunction of FIG. 3 has been extensively researched. a-Si:H has larger bandgap (1.7-1.9 eV) than Si (1.1 eV), and the heterojunction has a discontinuity at the conduction band (E_{C}) and valance band (E_{V}). A cell efficiency of 22.3% has been reported. Compared to the back contact cell, the heterojunction cell has larger V_{OC}, but lower short circuit current (I_{SC}) and lower fill factor (FF). The lower I_{SC} is caused by the shadowing effect of the metal grid at the front surface, and the lower FF is due to the grid resistance.

A heterojunction is the interface that occurs between two layers or regions of dissimilar semiconductors. These semiconducting materials have unequal band gaps. The engineering of electronic energy bands is also used in the design of semiconductor lasers and transistors. When a heterojunction is used as the base-emitter junction of a bipolar junction transistor, extremely high forward gain and low reverse gain result. This translates into very good high frequency operation (values in tens to hundreds of GHz) and low leakage currents. This device is called a heterojunction bipolar transistor (HBT).

The principle difference between a bipolar junction transistor (BJT) and the HBT is the use of differing semiconductor materials for the emitter and base regions, creating a heterojunction at the interface. The effect is to limit the injection of minority carriers into the emitter region and increase emitter efficiency, since the potential barrier in the valence band is so large at the heterojunction interface. Unlike BJT technology, this allows high doping to be used in the base, creating higher electron mobility while maintaining gain.

It is a common assumption that a solar cell that combines the advantages of back contact cell and heterojunction cell would have a higher efficiency than either one by itself. While several papers discuss a double heterojunction back contact solar cell, no simple and inexpensive means have been reported for integrating n-type a-Si and p-type a-Si on a single side of a solar cell.

Additionally, an anomalous “S” shaped I-V characteristic is often observed for Si double heterojunction back contact cells fabricated both on p- and n-type c-Si wafers. This “S” shaped I-V characteristic has been attributed to various mechanisms including carrier recombination at the interface defects, recombination in the c-Si depletion region, offset in valence band, and offset in conduction band. The band offset may impose potential barriers for transport of photogenerated carriers across the heterojunction, thereby affecting the fill factor.

FIGS. 4A and 4B are diagrams depicting ideal energy band offsets for heterojunctions that are, respectively, physically separated and in chemical equilibrium (prior art). As noted in Wikipedia, there are three relevant material properties for classifying a given junction, and understanding the charge dynamics at a heterojunction: band gap, electron affinity, and work function. The energy difference between the valence band (VB) and conduction band (CB), called the bandgap, is anywhere from 0 eV for a metal (there is no gap) to over 4 eV for an insulator. The work function of a material is the energy difference between the Fermi energy (chemical equilibrium energy) and the vacuum level (where electron removal occurs). Finally, the electron affinity of each material is needed which is the energy difference between the conduction band and the vacuum level.

Calculating energy band offsets for an ideal heterojunction is straightforward given these material properties using Anderson's rule. The conduction band offset depends only on the electron affinity difference between the two semiconductors:

ΔE_{C}=χ₁−χ₂=Δ_{χ}

Then using the change in bandgap:

ΔE_{G}=E_{G2}−E_{G1}

The valence band offset is simply given by:

ΔE_{V}=ΔE_{G}−Δ_{χ}

Which confirms the trivial relationship between band offsets and bandgap difference:

ΔE_{G}=ΔE_{C}+ΔE_{V}

In Anderson's idealized model these material parameters are unchanged when the materials are brought together to form an interface, so it ignores the quantum size effect, defect states and other perturbations which may or may not be the result of imperfect crystal lattice matches. When two materials are brought together and allowed to reach chemical/thermal equilibrium, the Fermi level in each material aligns and is constant throughout the system. To the extent that they are able, electrons in the materials leave some regions (depletion) and build up in others (accumulation) in order to find equilibrium. When this occurs a certain amount of band bending occurs near the interface. This total band bending can be quantified with the built in potential given by:

V_{bi}=φ₁−φ₂=(E_{G1}+χ₁−ΔE_{F1})−(χ₂+ΔE_{F2})

Where ΔE_{F1}=E_{F1}−E_{V1} and ΔE_{F2}=E_{C2}−E_{F2}

In most cases where the materials are undoped, these ΔE_{F} terms are just half the bandgap. Otherwise, ΔE_{F} can be calculated with typical solid state device calculations and depends on dopant concentrations and temperature. The built-in potential gives the degree to which band bending occurs but reveals nothing about how this happens spatially. In order to know over what distance the bending occurs in which materials, the density of states and state occupation given by the Fermi-Dirac distribution must be known.

In real semiconductor heterojunctions, Anderson's model fails to predict actual band offsets. The idealized model ignores the fact that each material is made up of a crystal lattice whose electrical properties depend on a periodic arrangement of atoms. This periodicity is broken at the heterojunction interface to varying degrees. In cases where both materials have the same lattice, they may still have differing lattice constants which give rise to a crystal strain that changes the band energies. In other cases the strain is relaxed via dislocations and other interfacial defects, which also change the band energies.

It would be advantageous if a solar cell could be efficiently fabricated at low process temperatures, and included the advantages of both heterojunctions and back contacts.

### SUMMARY OF THE INVENTION

Disclosed herein is a heterojunction back contact solar cell with heterojunctions formed between organic semiconductors, such as polymers, and silicon (Si) at both the n+and p+contacts. In order to have high interface quality, a thin intrinsic amorphous silicon layer is inserted between the silicon and organic semiconductor because of the good interface quality between hydrogenated amorphous silicon (a-Si:H) and single-crystal silicon (c-Si). The valance band discontinuity at the a-Si:H/c-Si interface prevents minority carriers (holes in n-type Si) from reaching the electron acceptor organic semiconductor (n-type), so surface recombination at the a-Si/n-type organic semiconductor interface is reduced. Similarly, the conduction band discontinuity at the a-Si:H/c-Si interface reduces the number of majority carriers (electron in n-type Si) reaching the electron donor organic semiconductor (p-type), which also reduces surface recombination at the a-Si/p-type organic semiconductor interface.

Accordingly, a method is provided for fabricating a back contact solar cell with organic semiconductor heterojunctions. A substrate is provided made from a first semiconductor of silicon lightly doped with a first dopant type having a first majority carrier. The substrate has a topside and a backside. The substrate topside is texturized and a second semiconductor layer is formed overlying the first semiconductor substrate topside, made from hydrogenated amorphous silicon (a-Si:H) and doped with the first dopant. An antireflective coating is formed overlying the second semiconductor layer. A third semiconductor layer is formed overlying the first semiconductor substrate backside, made from intrinsic a-Si:H. A first majority carrier type organic semiconductor layer is formed overlying the third semiconductor layer in a first pattern, where the first pattern includes channels in the first majority carrier type organic semiconductor, exposing the underlying third semiconductor layer. A second majority carrier type organic semiconductor layer in a second pattern is formed overlying the third semiconductor layer in the first majority carrier type organic semiconductor pattern channels. The second majority carrier is opposite in polarity to the first majority carrier. The second pattern of second majority carrier type organic semiconductor incompletely fills the channels in the first majority carrier type organic semiconductor, forming spaces between the first majority carrier type organic semiconductor layer and the second majority carrier type organic semiconductor layer, exposing the third semiconductor layer.

A dielectric organic semiconductor layer is formed overlying the first majority carrier type organic semiconductor layer and the second majority carrier type organic semiconductor layer, filling the spaces. Openings in the dielectric organic semiconductor layer expose the first majority carrier type organic semiconductor layer and the second majority carrier type organic semiconductor layer respectively forming first and second organic semiconductor contact regions. A first metal grid is connected to first organic semiconductor contact regions and a second metal grid is connected to the second organic semiconductor contact regions.

Additional details of the above-described method and a back contact solar cell with organic semiconductor heterojunctions are provided below.

### BRIEF DESCRIPTION OF THE DRAWINGS

FIG. 1 is a partial cross-sectional view of a conventional silicon solar cell (prior art).

FIG. 2 is a partial cross-sectional view depicting a back contact solar cell (prior art).

FIG. 3 is a perspective drawing depicting a heterojunction solar cell (prior art).

FIGS. 4A and 4B are diagrams depicting ideal energy band offsets for heterojunctions that are, respectively, physically separated and in chemical equilibrium (prior art).

FIG. 5 is a partial cross-sectional view of an exemplary back contact solar cell with organic semiconductor heterojunctions.

FIG. 6 is a partial cross-sectional view of a variation of the back contact solar cell of FIG. 5.

FIG. 7 is a band diagram of the solar cell of FIG. 5 with the exemplary organic semiconductor (p)/a-Si:H intrinsic (i)/c-Si (n)/a-Si:H (i)/organic semiconductor (n) structure.

FIGS. 8A through 8I are partial cross-sectional views depicting an exemplary process flow in the fabrication of the solar cell of FIG. 5.

FIG. 9 is a flowchart illustrating a method for fabricating a back contact solar cell with organic semiconductor heterojunctions.

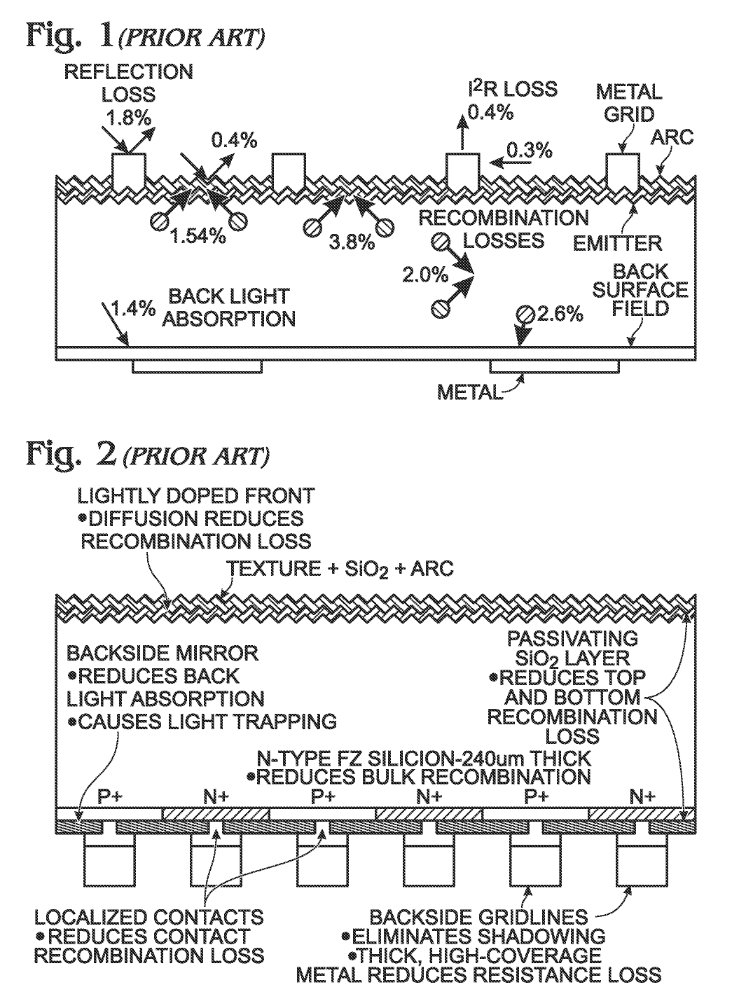

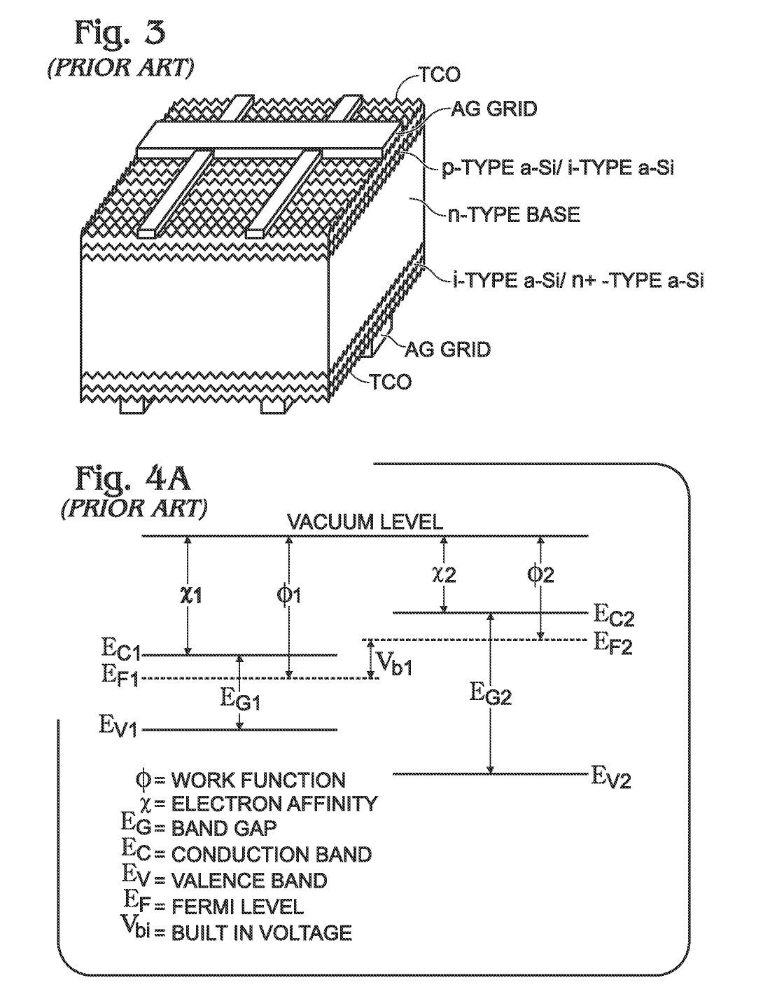

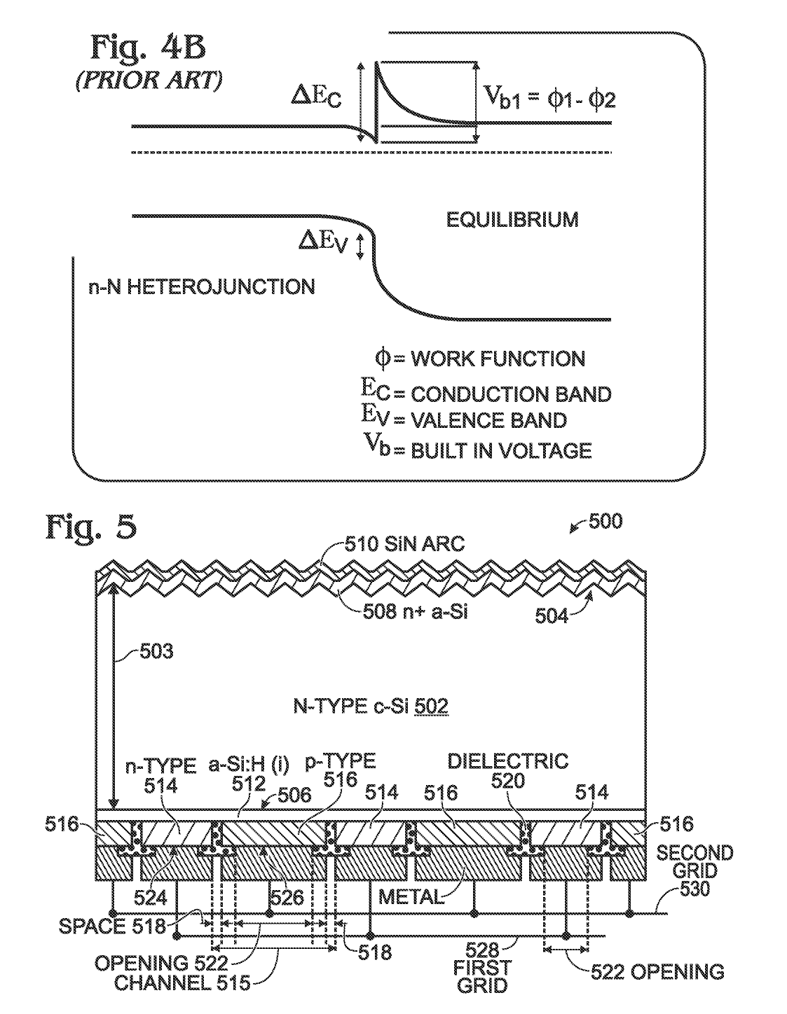

### DETAILED DESCRIPTION

FIG. 5 is a partial cross-sectional view of an exemplary back contact solar cell with organic semiconductor heterojunctions. The solar cell 500 comprises a substrate 502 made from a first semiconductor of silicon lightly doped with a first dopant type having a first majority carrier and a first energy bandgap. The substrate 502 has a textured topside 504 and a backside 506. The substrate 502 first semiconductor is typically single-crystal silicon or multi-crystalline silicon. As shown in this example, the substrate 502 is n-type single-crystal silicon (c-Si). The substrate first semiconductor 502 has a thickness 503 in a range of 2 to 400 microns, with a first dopant density in a range of 5×10¹⁴ to 1×10¹⁶ cm⁻³.

A second semiconductor layer 508 overlies the first semiconductor substrate textured topside 504, made from hydrogenated amorphous silicon (a-Si:H) and doped with the first dopant. In this example, the first dopant is an n-type material such as arsenic (As) or phosphorous (P). An antireflective coating (ARC) 510 overlies the second semiconductor layer 508. SiNx is one example of a material that can be used for the antireflective coating. A third semiconductor layer 512 overlies the first semiconductor substrate backside 506, made from intrinsic a-Si:H. The material of the third semiconductor layer 512 has a second energy bandgap that is larger than the first energy bandgap. If the substrate is a p-type silicon, then the second semiconductor layer would be p+ a-Si.

A first majority carrier type organic semiconductor layer 514 overlies the third semiconductor layer 512 in a first pattern. The first pattern includes channels 515 in the first majority carrier type organic semiconductor exposing the underlying third semiconductor layer. In this example, the first majority carrier type organic semiconductor is an n-type material with electron charge carriers. Since the electron charge density is high, the junction between the n-type organic semiconductor 514 and a-Si:H 512 is called an n+ contact. The first majority carrier type organic semiconductor has a third energy bandgap that is larger than the second energy bandgap.

Within organic semiconductors, the typical current carriers are holes and electrons through n-bonds. In general, organic semiconductors contain n-conjugated networks that facilitate the flow of carriers through either highly delocalized n-conjugated covalent bonds, and/or effective through-space overlap of n-electron clouds. Overall, organic semiconductors may be broadly classified as a collection of individual molecules, short chain (oligomeric) materials, and/or organic polymers, the latter two of which can be viewed collectively. Organic semiconductors may be further distinguished as either p-type or n-type. In p-type organic semiconductors, free positive charge carriers (holes) are predominate, while n-type materials exhibit an affinity for electrons due to an intrinsic electron deficiency in the material arising from high degrees of unsaturation, incorporation of electron-withdrawing moieties (fluorine or cyano groups, for example) and/or electron deficient atoms (boron) or, alternatively, from appropriate doping.

Typically, collections of individual, semiconducting (organic) molecules consist of polycyclic aromatic or hetero-aromatic compounds which include, but are not limited to, anthracene, pentacene, rubrene, perylene, perylene dimides, phthalocyanines, arylamines, three-dimensionsal carbon frameworks such as [60]fullerene and higher analogues as well as functional derivatives and combinations thereof.

Oligomeric and polymeric semi-conductor molecules can be considered together since they consist of repeating units of a single molecule or alternating units of chemically different organic building blocks that differ only in polymer chain length. Typically, the introduction of heteroatoms leads to p-type behavior, although this is not a universal phenomenon. In general, intrinsically conducting polymers (or oligomers) may either exhibit metallic conductivity or be classified as semiconductors. Although the mostly widely utilized polymer organic semiconductors include polythiophenes, polyacetylenes, polypyrroles, polyanilines, poly-p-phenylenevinylenes, poly-3,4-ethylenedioxythiophenes (PEDOT) and poly-p-phenylene sulfides, additional polymeric materials such as polyfluorenes, polyphenylenes, polypyrenes, polyazulenes, polynaphathalenes, polycarbazoles, polyindoles, polyazepines, etc. may also be considered in addition to extended carbon networks such as carbon nanotubes and graphenes as well as functional derivatives and combinations thereof.

The conduction mechanisms for organic semiconductors may proceed through tunneling, hopping between localized states, mobility gaps or related processes. As is the case for inorganic semiconductors, the conductivity of organic semiconductors can be favorably manipulated through the incorporation of an appropriate dopant. Essentially, there exist two major categories for organic semiconductors which include charge-transfer complexes and various linear-backbone conductive polymers such as those derived from polyacetylene, polypyrrole and polyaniline. Usually, charge-transfer complexes exhibit similar conduction mechanisms to inorganic semiconductors, at least locally, whereby such mechanisms arise from the presence of hole and electron conduction layers effectively separated by a band gap.

Overall, p-type organic semiconductors have been investigated exhaustively due to appreciable stability towards atmospheric and processing conditions. In contrast, the high-sensitivity of n-type organic materials to environmental and thermal stresses (leading to deterioration and reduced performance) has proven to be a challenge towards the development and integration of such materials. Nevertheless, several classes of n-type organic materials can be successfully employed and include, but are not limited to, collections of individual or oligomeric/polymeric arylene diimides (naphthalene, perylene, etc.), [60]fullerene and higher fullerene analogues including functionalized fullerene derivatives such as [6,6]-phenyl-C₆₁-butyric acid methyl ester (PCBM) and/or indene-C₆₀ bisadduct (ICBA, Luminescence Technology Corporation) or similar, poly[2-methoxy-5-(2′-ethylhexyloxy)-1,4-(1-cyanovinylene)-phenylene] (CN-MEH-PPV), poly(9,9′-dioctylfluoreneco-benzothiadiazole) (F8BT), perfluoro-terthiophenes, boron-doped polymers such as Boramer™-T01(poly-1,4-divinylenephenylene tripylborane) and Boramer™-T03 (poly-2,5-didecyloxy-1,4-phenylene tripylborane, diphenyl terminated) (TDA Research, Inc.) and functionalized carbon nanotubes, including derivatives and combinations thereof.

A second majority carrier type organic semiconductor layer 516 is formed in a second pattern overlying the third semiconductor layer 512 in the first majority carrier type organic semiconductor pattern channels 515. The second majority carrier is opposite in polarity to the first majority carrier. In this example, the second majority carrier type organic semiconductor is p-type. Since the electron charge density is high, the junction between the p-type organic semiconductor 516 and the third semiconductor layer 512 is called an p+ contact. p-type examples include polythiophenes, polyacetylenes, polypyrroles, polyanilines, poly-p-phenylenevinylenes, poly-3,4-ethylenedioxythiophenes (PEDOT) and poly-p-phenylene sulfides, additional polymeric materials such as polyfluorenes, polyphenylenes, polypyrenes, polyazulenes, polynaphathalenes, polycarbazoles, polyindoles, polyazepines, etc. may also be considered in addition to extended carbon networks such as carbon nanotubes and graphenes as well as functional derivatives and combinations thereof.

The second pattern of second majority carrier type organic semiconductor 516 incompletely fills the channels 515 in the first majority carrier type organic semiconductor, forming spaces 518 between the first majority carrier type organic semiconductor layer 514 and the second majority carrier type organic semiconductor layer 516, exposing the third semiconductor layer 512. The second majority carrier type organic semiconductor has a fourth bandgap that is larger than the second energy bandgap. The first and second majority carrier type organic semiconductor layers 514/516 each have a charge carrier density in a range of 5×10¹⁸ to 5×10²⁰ cm⁻³ and a resistivity in a range of 1×10⁻³ to 10 ohm-cm.

A dielectric organic semiconductor layer 520 overlies the first majority carrier type organic semiconductor layer 514 and the second majority carrier type organic semiconductor layer 516, filling the spaces 518. Openings 522 in the dielectric organic semiconductor layer 520 expose the first majority carrier type organic semiconductor layer 514 and the second majority carrier type organic semiconductor layer 516 that respectively forms first organic semiconductor contact regions 524 and second organic semiconductor contact regions 526. A first metal grid 528 connects first organic semiconductor contact regions 524, and a second metal grid 530 connects second organic semiconductor contact regions 526. The first and second metal grids 528/530 can be made from a metal such as Al, Ag, or Ti.

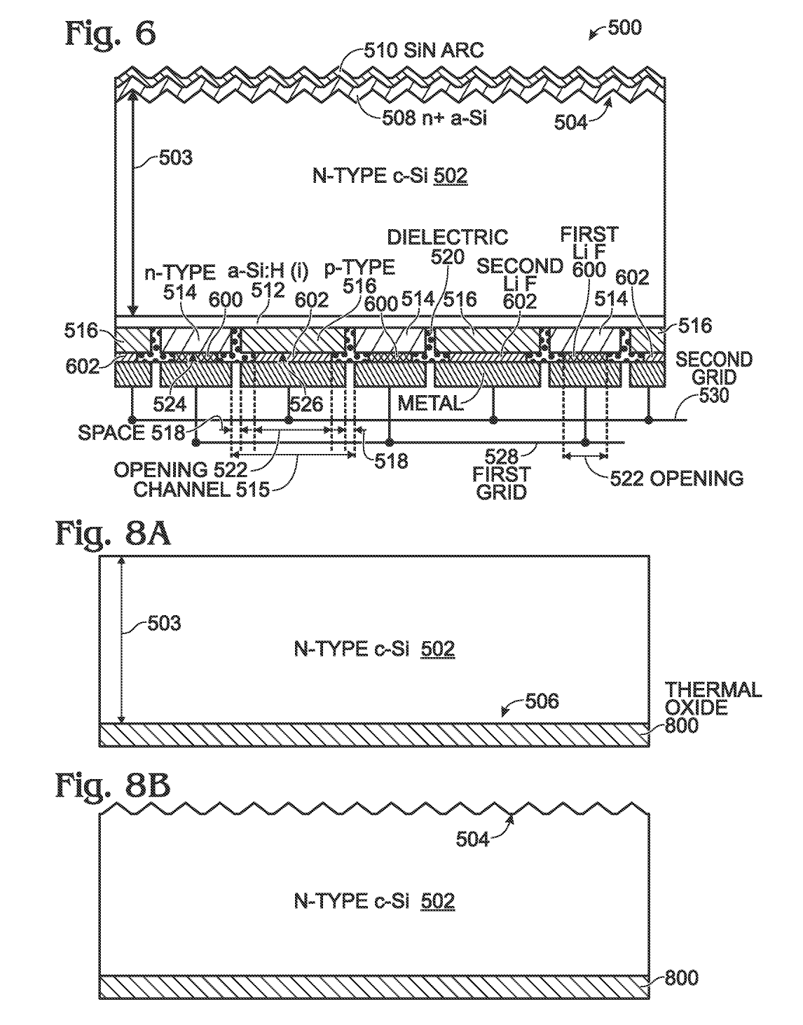

FIG. 6 is a partial cross-sectional view of a variation of the back contact solar cell of FIG. 5. The solar cell 500 of FIG. 6 is the same as the one depicted in FIG. 5, except it further comprises a first LiF layer 600 interposed between the first organic semiconductor contact regions 524 and the first metal grids 528. A second LiF layer 602 is interposed between the second organic semiconductor contact regions 526 and the second metal grids 530.

Referencing either FIG. 5 or 6, the first dopant may be an n-type dopant material (e.g., phosphorous) and the second dopant is a p-type dopant material (e.g., boron). Alternatively, the first dopant may be a p-type material and the second dopant an n-type material. As used herein, a heavily doped region, e.g., a heavily p doped region, is referred to as p+ (p+ doped), and is associated with dopant concentrations in the range of about 1×10¹⁹ to 1×10²¹ cm⁻³. Regions with this degree of dopant are often contact areas. A moderately doped region, e.g., a moderately p doped region, is referred to as p (p doped or p-doped), and is associated with dopant concentrations in the range of about 5×10¹⁶ to 1×10¹⁹ cm⁻³. A lightly doped region, e.g., a lightly p doped region, is referred to as p− (p− doped), and is associated with dopant concentrations in the range of about 1×10¹⁵ to 5×10¹⁶ cm⁻³. For the n-type layers, the doping concentrations are the same as for p-type dopants, as stated above. The term “n-type” refers to any amount of n doping. Likewise, “p-type” refers to any level of p doping.

### Functional Description

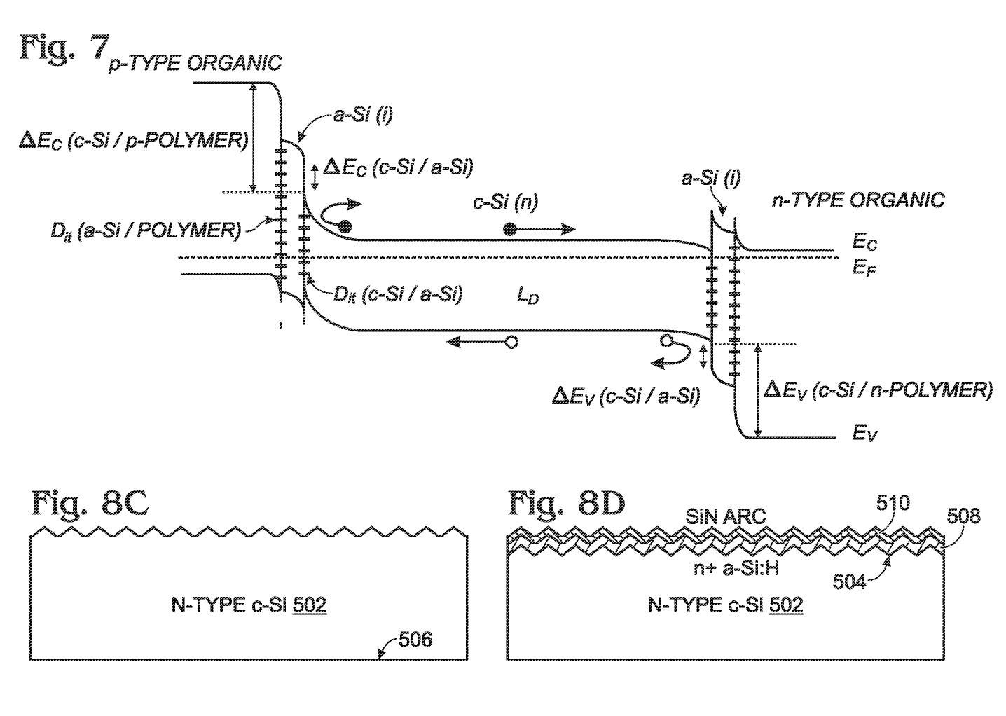

FIG. 7 is a band diagram of the solar cell of FIG. 5 with the exemplary organic semiconductor (p)/a-Si:H intrinsic (i)/ c-Si (n)/a-Si:H (i)/organic semiconductor (n) structure. The movement of photo-generated carriers for this band structure is as follows:

(a) Electron/hole pairs are generated in the body of the N-type c-Si by absorption of photons.

(b) Electrons can move to either terminal.
1) electrons that move to the c-Si / organic semiconductor (p) interface see the barrier height ΔEc (c-Si/a-Si) and are reflected;
2) electrons that move to the c-Si/organic semiconductor (n) interface tunnel though the low barrier created by the a-Si (i) layer and are collected by the n-type organic semiconductor and external circuitry.

(c) Holes can move to either terminal.
1) holes that move to the c-Si/organic semiconductor (n) interface see the barrier height ΔE_{V} (c-Si /a-Si) and are reflected;
2) holes that move to the c-Si/organic semiconductor (p) interface tunnel though the a-Si (i) layer and are collected by the p-type organic semiconductor and external circuitry and this completes the circuit.

There are several advantages to using a-Si(i) as a buffer layer between the c-Si and organic semiconductor, which can be explained using the band diagram of FIG. 7. The interface state Dᵢₜ at the interface between c-Si and a-Si is easier to control than the c-Si-to-organic semiconductor interface. Therefore, the low Dᵢₜ density at the c-Si and a-Si interfaces reduces the diode saturation current, and increases the V_{OC} of the solar cell. Although higher interface state density at the a-Si to organic semiconductor interface, Dᵢₜ (a-Si/organic semiconductor) is expected, electrons are blocked by the ΔE_{C} (c-Si/a -Si) barrier and holes are blocked by the ΔE_{V} (c-Si/a -Si) barrier. Therefore, the defect density at the organic semiconductor interface does not affect recombination and the surface recombination rate is low.

The interface quality of the metal-to-organic semiconductor contact does not play any role in this structure, since the ΔE_{C} (c-Si/p-organic semiconductor) and ΔE_{V} (c-Si/ n-organic semiconductor) can be very high. The electrons and holes are difficult to move across the ΔE_{C} (c-Si/p-organic semiconductor) and ΔE_{V} (c-Si /n-organic semiconductor), respectively. Note that the n-type organic semiconductor and p-type organic semiconductor are different materials, so that ΔE_{C}+ΔE_{V} is larger than difference between the organic semiconductor and Si band gap.

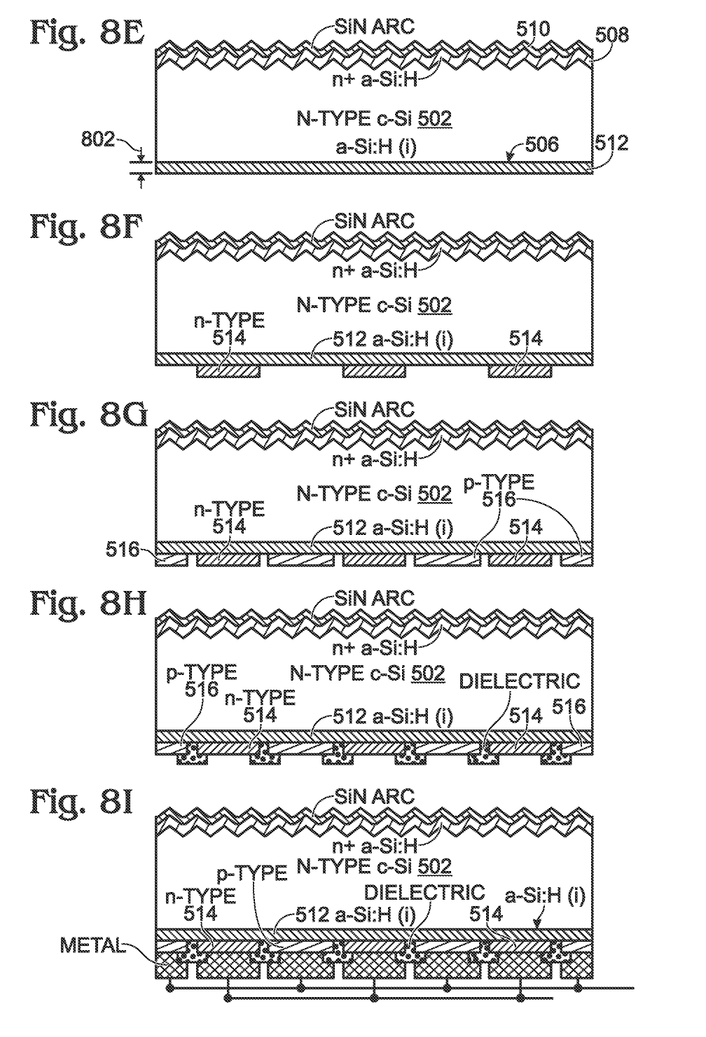

FIGS. 8A through 8I are partial cross-sectional views depicting an exemplary process flow in the fabrication of the solar cell of FIG. 5. The device can be completed using four alignment processes. It should be understood that the process flow described below is one example of many possible fabrication processes, and the fabrication of the solar cell is not limited to just this example.

In FIG. 8A the process starts with either lightly doped n-type or p-type silicon 502, with n-type silicon being used for this example. If p-type silicon is used, the dopant in the following process changes to opposite polarity (n to p, p to n). The silicon 502 can be either single crystalline or multi-crystalline with a thickness 503 of 2 μm to 400 μm. For example, the phosphorous dopant density is between 5×10¹⁴ and 1×10¹⁶ cm⁻³. Thermal oxide 800 is grown on the wafer backside 506.

In FIG. 8B single topside texturing is performed. Alkaline etchants, such as NaOH and KOH, are used to form a pyramidal etch structure on the front (top) side of the wafer 504. The oxide layer 800 protects the back side 506.

In FIG. 8C the oxide is removed from the wafer backside 506.

In FIG. 8D, a-Si:H (n) 508 is deposited on the wafer front surface 504 to form a front surface field region that reduces surface recombination. Then, SiNx 510 is deposited, by plasma-enhanced chemical vapor deposition (PECVD), on front surface 504 to form an anti-reflection layer. Alternatively but not shown, an intrinsic a-Si:H layer can be deposited between a-Si:H (n) and c-Si with thickness of ˜1 nm to 20 nm.

In FIG. 8E, an a-Si:H (i) layer 512 is deposited on wafer backside 506. The thickness 802 is less than 10 nm.

In FIG. 8F the n-type organic semiconductor layer is deposited. This organic semiconductor deposition is by screen printing or by inkjet printing to form the n-type pattern (first alignment). The n-type organic semiconductor is an electron acceptor material, such as one of the above-listed materials.

In FIG. 8G the p-type organic semiconductor layer is deposited. This organic semiconductor deposition is by screen printing or by inkjet printing to form the p-type pattern (second alignment). The p-type organic semiconductor is an electron donor material, such as one of the above-listed materials.

In FIG. 8H the dielectric organic semiconductor layer is deposited. This organic semiconductor deposition is by screen printing or by inkjet printing to form a pattern of openings to contact the n and p-type organic semiconductor patterns (third alignment). The organic semiconductor dielectric provides electrical isolation between n-type and p-type organic semiconductors, and forms contact regions for the metal layer.

In FIG. 8I metal is deposited to form the electrode. All n-type organic semiconductor regions are connected together, and all p-type organic semiconductors are connected together. The metal layer can be deposited by vacuum deposition and then etched to form the pattern, or it can be screen printed or inkjet printed, which does not require etching to form the pattern (fourth alignment). A shadow mask can use in the vacuum deposition. This way, the patterned structure does not need to be etched. The metal can be Al, Ag, Ti or any suitable material. LiF can be deposited between the organic semiconductors and the metal electrode to improve conduction (FIG. 6).

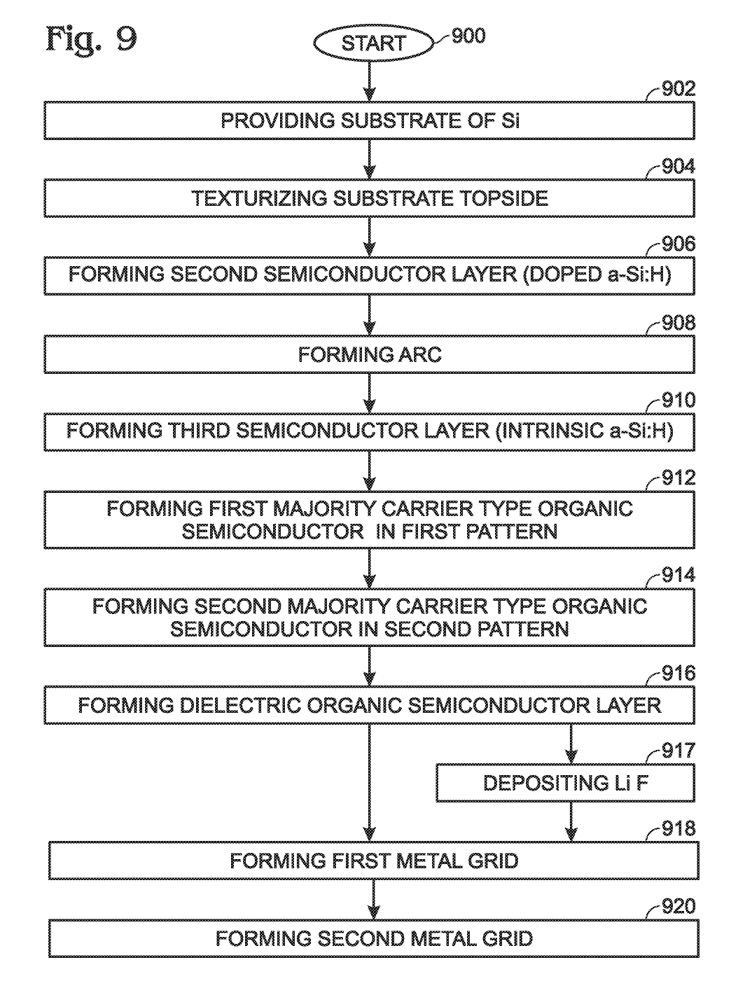

FIG. 9 is a flowchart illustrating a method for fabricating a back contact solar cell with organic semiconductor heterojunctions. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 900.

Step 902 provides a substrate made from a first semiconductor of silicon lightly doped with a first dopant type having a first majority carrier. The substrate has a topside and a backside. The substrate first semiconductor is typically either single-crystal silicon or multi-crystalline silicon. The substrate first semiconductor has a thickness in the range of 2 to 400 microns, with a first dopant density in the range of 5×10¹⁴ to 1×10¹⁶ cm⁻³. Step 904 textures the substrate topside. Step 906 forms a second semiconductor layer overlying the first semiconductor substrate topside, made from hydrogenated amorphous silicon (a-Si:H) and doped with the first dopant. Step 908 forms an antireflective coating (ARC) overlying the second semiconductor layer.

Step 910 forms a third semiconductor layer overlying the first semiconductor substrate backside, made from intrinsic a-Si:H. In one aspect, the a-Si:H is doped with oxygen and/or carbon to form a semiconductor with a larger bandgap than a-Si:H. Step 912 forms a first majority carrier type organic semiconductor layer overlying the third semiconductor layer in a first pattern, where the first pattern includes channels in the first majority carrier type organic semiconductor exposing the underlying third semiconductor layer. Step 914 forms a second majority carrier type organic semiconductor layer in a second pattern overlying the third semiconductor layer in the first majority carrier type organic semiconductor pattern channels. The second majority carrier is opposite in polarity to the first majority carrier. The second pattern of second majority carrier type organic semiconductor incompletely fills the channels in the first majority carrier type organic semiconductor, forming spaces between the first majority carrier type organic semiconductor layer and the second majority carrier type organic semiconductor layer, exposing the third semiconductor layer.

Forming the first majority carrier type organic semiconductor layer in Step 912 includes using a screen printing or inkjet printing to deposit the first pattern as a sequence of stripes. Likewise, forming the second majority carrier type organic semiconductor in Step 914 layer includes using a screen printing or inkjet printing to deposit the second pattern as a sequence of stripes. (n)-type organic semiconductors include collections of individual or oligomeric/polymeric arylene diimides (naphthalene, perylene, etc.), [60]fullerene and higher fullerene analogues including functionalized fullerene derivatives such as [6,6]-phenyl-C₆₁-butyric acid methyl ester (PCBM) and/or indene-C₆₀ bisadduct (ICBA, Luminescence Technology Corporation) or similar, poly[2-methoxy-5-(2′-ethylhexyloxy)-1,4-(1-cyanovinylene)-phenylene] (CN-MEH-PPV), poly(9,9′-dioctylfluoreneco-benzothiadiazole) (F8BT), perfluoro-terthiophenes, boron-doped polymers such as Boramer™-T01 (poly-1,4-divinylenephenylene tripylborane) and Boramer™-T03 (poly-2,5-didecyloxy-1,4-phenylene tripylborane, diphenyl terminated) (TDA Research, Inc.) and functionalized carbon nanotubes, including derivatives and combinations thereof.

(p)-type organic semiconductors include polythiophenes, polyacetylenes, polypyrroles, polyanilines, poly-p-phenylenevinylenes, poly-3,4-ethylenedioxythiophenes (PEDOT) and poly-p-phenylene sulfides, additional polymeric materials such as polyfluorenes, polyphenylenes, polypyrenes, polyazulenes, polynaphathalenes, polycarbazoles, polyindoles, polyazepines, etc. may also be considered in addition to extended carbon networks such as carbon nanotubes and graphenes as well as functional derivatives and combinations thereof.

Each of the first and second majority carrier type organic semiconductor layers have a charge carrier density in the range of 5×10¹⁸ to 5×10²⁰ cm⁻³ and a resistivity in the range of 1×10⁻³ to 10 ohm-cm.

Step 916 forms a dielectric organic semiconductor layer overlying the first majority carrier type organic semiconductor layer and the second majority carrier type organic semiconductor layer, filling the spaces. The dielectric organic semiconductor layer has openings exposing the first majority carrier type organic semiconductor layer and the second majority carrier type organic semiconductor layer that form, respectively, first and second organic semiconductor contact regions. The dielectric organic semiconductor is deposited using a process selected a screen printing or inkjet printing process.

Step 918 forms a first metal grid connecting first organic semiconductor contact regions. Step 920 forms a second metal grid connecting second organic semiconductor contact regions. The first and second metal grids are formed by a deposition process such as vacuum deposition, screen printing, or inkjet printing. The first and second metal grids includes may be formed from Al, Ag, or Ti. In one aspect, prior to forming the first and second metal grids, Step 717 deposits LiF overlying the first and second organic semiconductor contact regions.

A back contact solar cell with organic semiconductor heterojunctions and an associated fabrication process have been presented. Specific structures, materials, and processes have been given to illustrate the invention. However, the invention is not limited to merely these examples. Other variations and embodiments of the invention will occur to those skilled in the art.

We claim:

1. A method for fabricating a back contact solar cell with organic semiconductor heterojunctions, the method comprising:
providing a substrate made from a first semiconductor of silicon lightly doped with a first dopant type having a first majority carrier, the substrate having a topside and a backside;
texturing the substrate topside;
forming a second semiconductor layer overlying the first semiconductor substrate topside, made from hydrogenated amorphous silicon (a-Si:H) and doped with the first dopant;
forming an antireflective coating overlying the second semiconductor layer;
forming a third semiconductor layer overlying the first semiconductor substrate backside, made from intrinsic a-Si:H;
forming a first majority carrier type organic semiconductor layer overlying the third semiconductor layer inn a first pattern, where the first pattern includes channels in the first majority carrier type organic semiconductor exposing the underlying third semiconductor layer;
forming a second majority carrier type organic semiconductor layer in a second pattern overlying the third semiconductor layer in the first majority carrier type organic semiconductor pattern channels, where the second majority carrier is opposite in polarity to the first majority carrier, and where the second pattern of second majority carrier type organic semiconductor incompletely fills the channels in the first majority carrier type organic semiconductor, forming spaces between the first majority carrier type organic semiconductor layer and the second majority carrier type organic semiconductor layer, exposing the third semiconductor layer;
forming a dielectric organic semiconductor layer overlying the first majority carrier type organic semiconductor layer and the second majority carrier type organic semiconductor layer, filling the spaces, with openings exposing the first majority carrier type organic semiconductor layer and the second majority carrier type organic semiconductor layer that respectively form first and second organic semiconductor contact regions;
forming a first metal grid connected to first organic semiconductor contact regions; and,
forming a second metal grid connected to second organic semiconductor contact regions.

2. The method of claim 1 wherein providing the substrate includes the first semiconductor being a material selected from a group consisting of single-crystal silicon and multi-crystalline silicon,

3. The method of claim 2 wherein providing the substrate includes first semiconductor having a thickness in a range of 2 to 400 microns, with a first dopant density in a range of 5×10¹⁴ to 1×10¹⁶ cm⁻³.

4. The method of claim 1 wherein forming the first majority carrier type organic semiconductor layer includes using a process selected from a group consisting of screen printing and inkjet printing to deposit the first pattern as a sequence of stripes; and,
wherein forming the second majority carrier type organic semiconductor layer includes using a process selected from the group consisting of screen printing and inkjet printing to deposit the second pattern as a sequence of stripes.

5. The method of claim 1 wherein depositing the first and second majority carrier type organic semiconductor layers includes depositing an n-type organic semiconductor selected from a group consisting of oligomeric/polymeric arylene diimides (naphthalene, perylene, etc.), [60]fullerene and higher fullerene analogues, poly[2-methoxy-5-(2′-ethylhexyloxy)-1,4-(1-cyanovinylene)-phenylene] (CN-MEH-PPV), poly(9,9′-dioctylfluoreneco-benzothiadiazole) (F8BT), perfluoro-terthiophenes, boron-doped polymers, and functionalized carbon nanotubes, including derivatives and combinations thereof.

6. The method of claim 1 wherein depositing the first and second majority carrier type organic semiconductor layers includes depositing a p-type organic semiconductor selected from a group consisting of polythiophenes, polyacetylenes, polypyrroles, polyanilines, poly-p-phenylenevinylenes, poly-3,4-ethylenedioxythiophenes (PEDOT) and poly-p-phenylene sulfides, polyfluorenes, polyphenylenes, polypyrenes, polyazulenes, polynaphathalenes, polycarbazoles, polyindoles, polyazepines, carbon nanotubes, and graphenes including functional derivatives and combinations thereof.

7. The method of claim 1 wherein forming the dielectric organic semiconductor layer overlying the first and second majority carrier type organic semiconductor layers includes depositing the dielectric organic semiconductor using a process selected from a group consisting of screen printing and inkjet printing.

8. The method of claim 1 wherein forming the first and second metal grids includes using a deposition process selected from a group consisting of vacuum deposition, screen printing, and inkjet printing.

9. The method of claim 1 wherein forming the first and second metal grids includes forming the first and second metal grids from a material selected from a group consisting of Al, Ag, and Ti.

10. The method of claim 1 further comprising:
prior to forming the first and second metal grids, depositing LiF overlying the first and second organic semiconductor contact regions.

11. The method of claim 1 wherein forming the first and second majority carrier type organic semiconductor layers includes forming each organic semiconductor layer with a charge carrier density in a range of 5×10¹⁸ to 5×10²⁰ cm⁻³ and a resistivity in a range of 1×10⁻³ to 10 ohm-cm.

12. A back contact solar cell with organic semiconductor heterojunctions, the solar cell comprising:
a substrate made from a first semiconductor of silicon lightly doped with a first dopant type having a first majority carrier, the substrate having a textured topside and a backside;
a second semiconductor layer overlying the first semiconductor substrate textured topside, made from hydrogenated amorphous silicon (a-Si:H) and doped with the first dopant;
an antireflective coating overlying the second semiconductor layer;
a third semiconductor layer overlying the first semiconductor substrate backside, made from intrinsic a-Si:H;
a first majority carrier type organic semiconductor layer overlying the third semiconductor layer in a first pattern, where the first pattern includes channels in the first majority carrier type organic semiconductor exposing the underlying third semiconductor layer;
a second majority carrier type organic semiconductor layer formed in a second pattern overlying the third semiconductor layer in the first majority carrier type organic semiconductor pattern channels, where the second majority carrier is opposite in polarity to the first majority carrier, and where the second pattern of second majority carrier type organic semiconductor incompletely fills the channels in the first majority carrier type organic semiconductor, forming spaces between the first majority carrier type organic semiconductor layer and the second majority carrier type organic semiconductor layer, exposing the third semiconductor layer;
a dielectric organic semiconductor layer overlying the first majority carrier type organic semiconductor layer and the second majority carrier type organic semiconductor layer, filling the spaces;
openings in the dielectric organic semiconductor layer exposing the first majority carrier type organic semiconductor layer and the second majority carrier type organic semiconductor layer that respectively form first and second organic semiconductor contact regions;
a first metal grid connected to first organic semiconductor contact regions; and, a second metal grid connected to second organic semiconductor contact regions.

13. The solar cell of claim 12 wherein the substrate first semiconductor is a material selected from a group consisting of single-crystal silicon and multi-crystalline silicon.

14. The solar cell of claim 13 wherein the substrate first semiconductor has a thickness in a range of 2 to 400 microns, with a first dopant density in a range of 5×10¹⁴ to 1×10 cm⁻³.

15. The solar cell of claim 12 wherein the first or second majority carrier type organic semiconductor layer is an n-type organic semiconductor selected from a group consisting of oligomeric/polymeric arylene diimides (naphthalene, perylene, etc.), [60]fullerene and higher fullerene analogues, poly [2-methoxy-5-(2′-ethylhexyloxy)-1,4-(1-cyanovinylene)-phenylene] (CN -MEH-PPV), poly(9,9′-dioctylfluoreneco-benzothiadiazole) (F8BT), perfluoro-terthiophenes, boron-doped polymers, and functionalized carbon nanotubes, including derivatives and combinations thereof.

16. The solar cell of claim 12 wherein the first or second majority carrier type organic semiconductor layer is a p-type organic semiconductor selected from a group consisting of polythiophenes, polyacetylenes, polypyrroles, polyanilines, poly-p-phenylenevinylenes, poly-3,4-ethylenedioxythiophenes (PEDOT) and poly-p-phenylene sulfides, polyfluorenes, polyphenylenes, polypyrenes, polyazulenes, polynaphathalenes, polycarbazoles, polyindoles, polyazepines, carbon nanotubes, and graphenes including functional derivatives and combinations thereof.

17. The solar cell of claim 12 wherein the first and second metal grids are each a material selected from a group consisting of Al, Ag, and Ti.

18. The solar cell of claim 12 further comprising:
a first LiE layer interposed between the first organic semiconductor contact regions and the first metal grids; and,
a second UT layer interposed between the second organic semiconductor contact regions and the second metal grids.

19. The solar cell of claim 12 wherein the first and second majority carrier type organic semiconductor layers each have a charge carrier density in a range of 5×10¹⁸ to 5×10²⁰ cm⁻³ and a resistivity in a range of 1×10⁻³ to 10 ohm-cm.

20. A back contact solar cell with organic semiconductor heterojunctions, the solar cell comprising;
a substrate made from a first semiconductor of silicon lightly doped with a first dopant type having a first majority carrier and a first energy bandgap, the substrate having a textured topside and a backside;
a second semiconductor layer overlying the first semiconductor substrate textured topside, made from hydrogenated amorphous silicon (a-Si:H) and doped with the first dopant;
an antireflective coating overlying the second semiconductor layer;
a third semiconductor layer overlying the first semiconductor substrate backside, made from intrinsic a-Si:H having a second energy gap larger than the first energy gap;
a first majority carrier type organic semiconductor layer, having a third energy bandgap larger than the second energy bandgap, overlying the third semiconductor layer in a first pattern, where the first pattern includes channels in the first majority carrier type organic semiconductor exposing the underlying third semiconductor layer;
a second majority carrier type organic semiconductor layer, having a fourth energy bandgap larger than the second energy gap, formed in a second pattern overlying the third semiconductor layer in the first majority carrier type organic semiconductor pattern channels, where the second majority carrier is opposite in polarity to the first majority carrier, and where the second pattern of second majority carrier type organic semiconductor incompletely fills the channels in the first majority carrier type organic semiconductor, forming spaces between the first majority carrier type organic semiconductor layer and the second majority carrier type organic semiconductor layer, exposing the third semiconductor layer;
a dielectric organic semiconductor layer overlying the first majority carrier type organic semiconductor layer and the second majority carrier type organic semiconductor layer, filling the spaces;
openings in the dielectric organic semiconductor layer exposing the first majority carrier type organic semiconductor layer and the second majority carrier type organic semiconductor layer that respectively form first and second organic semiconductor contact regions;
a first metal grid connected to first organic semiconductor contact regions; and,
a second metal grid connected to second organic semiconductor contact regions.
